(19) United States
(12) Patent Application Publication
(10) Pub. No.: US 2007/0172696 A1
(43) Pub. Date: Jul. 26, 2007

(54) Protective thin film layers and methods of dielectric passivation of organic materials using assisted deposition processes

(75) Inventors: Wusheng Tong, Kennesaw, GA (US); Brent Wagner, Marietta, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Georgia Tech Research Corporation

(21) Appl. No.: 11/654,231

(22) Filed: Jan. 17, 2007

Related U.S. Application Data
(60) Provisional application No. 60/759,470, filed on Jan. 17, 2006.

(51) Int. Cl. B05D 7/00; B32B 19/00; B32B 9/04

(52) U.S. Cl. 428/689; 427/407.1; 428/698; 428/702; 428/704

(57) ABSTRACT

Methods of forming thin film layers and structures including the thin film layer are disclosed herein.

### CROSS REFERENCE TO RELATED APPLICATION

This application claims priority to U.S. provisional application entitled, “Protective Thin Film Layers and Methods of Dielectric Passivation of Organic Materials Using Assisted Deposition Processes”, having Ser. No. 60/759,470, filed on Jan. 17, 2006, which is entirely incorporated herein by reference.

### TECHNICAL FIELD

The present disclosure is generally related to protective thin films for electronic devices.

### BACKGROUND

Essentially all of today's microelectronic devices are made from inorganic materials—silicon and gallium arsenide being principle among them. Recently, devices made from organic molecules have been gaining attention. Although still in the early stages of development, significant progress has been achieved. One of their key distinguishing features is their compatibility with flexible substrates that makes them amenable to applications not possible with their inorganic counterparts. They also have the potential for low-cost and low-temperature processing making them attractive for the commercial market.

Various manufacturers are already exploiting organic light emitting diodes (OLED) as a viable alternative technology for flat panel displays. They are also gaining a considerable amount of attention as candidates for room lighting. However, the critical issue that hinders market applications for organic electronics is the long-term stability of the devices during operation. In large part, this is limited by the degradation of the device caused by the interaction between the activating layers and the potential contaminators existing in the environment such as oxygen or moisture during device operation. For example, the formation of dark centers was discovered when organic layers were exposed to air. Without protection these dark regions multiplied quickly and caused device failure. In addition, because of the intrinsic nature of organic materials, they are extremely sensitive to temperature. This leads to difficulties applying conventional packaging methods to organic electronic devices. This greatly increases production costs and limits low-cost markets.

Thus, a heretofore unaddressed need exists in the industry to address some of the aforementioned deficiencies and/or inadequacies.

### SUMMARY

Methods of forming thin film layers and structures including the thin film layer are disclosed herein. An embodiment of a method of forming a thin film layer, among others, includes: providing a layer of an organic material; and forming a thin film of a material onto the layer of organic material at a temperature of about 25 to 150° C. and at an energy of about 40 to 300 eV, wherein the layer of organic material is not damaged and wherein the thin film has a refractive index of about 1.4 to 2.3.

An embodiment of a method of forming a thin film layer, among others, includes: a thin film layer deposited on a layer of an organic material, wherein the thin film has a refractive index of about 1.4 to 2.3, and wherein the thin film is an environmental barrier that protects the layer of organic material from environmental agents.

### BRIEF DESCRIPTION OF THE DRAWINGS

Many aspects of the disclosed devices and methods can be better understood with reference to the following drawings and images. The components in the drawings are not necessarily to scale, emphasis instead being placed upon clearly illustrating the relevant principles. Moreover, in the drawings, like reference numerals designate corresponding parts throughout the several views.

FIG. 1 illustrates an embodiment of an Ion Assisted Deposition (IAD) with an Advanced Plasma Source system.

FIGS. 2A through 2B illustrate digital images of a multi-pocket e-beam evaporator and four thermal evaporators that may be included in the IAD-APS system shown in FIG. 1.

FIG. 3 illustrates the water content of coated and uncoated CR 39 lenses versus the storage time at about a 95% r.h.

FIG. 4 shows a digital image of an atomic force microscope (AFM) scan of SiON deposited on silicon.

FIGS. 5A through 5B illustrate profile analyses of gratings. FIG. 5A illustrates a profile analysis of uncoated grating, and FIG. 5B illustrates a profile analysis of grating coated with ZnS by the IAD process.

FIG. 6 illustrates a digital image of a scanning electron microscope (SEM) cross section of multilayer films showing dense amorphous microstructure.

FIGS. 7A through 7D illustrate digital images of an H₂O permeation test using a Ca metal. FIG. 7A illustrates a Ca metal film that is coated with SiON film after about 7 months. FIG. 7B illustrates a Nomarski picture of the Ca metal film shown in FIG. 7A. FIG. 7C illustrates a Nomarski picture of a melting Ca surface.

FIGS. 8A through 8C illustrate photoluminescence (PL) results of accelerated aging studies. FIG. 8A illustrates the PL intensity versus the number of weeks for a sample (PVK (poly(n-vinyl carbazole)) spin-coated on Si substrate) that is coated with a SiON film and a sample that is not coated. FIG. 8B illustrates a digital image of the samples at about 0 weeks, and FIG. 8C illustrates a digital image of the samples at about 3 weeks aging.

### DETAILED DESCRIPTION

Embodiments of the present disclosure provide for structures having a thin film or a combination of thin films (a multilayer thin film) deposited on a layer of an organic material (organic layer) and methods of forming the thin films on the organic layer. Typically the organic layer is part of an electronic device. In this regard, the thin film acts as an environmental barrier that protects the layer of organic material from environmental agents such as, but not limited to, air (e.g., oxygen), moisture, and combinations thereof, for extended periods of time commensurate with the lifetime of the device in which the structure is used. It should also be noted that the thin film protects the inorganic electrode materials (e.g., Ca, Li, Mg, and the like) of the electronic devices described herein.

In particular, embodiments of the present disclosure provide methods of forming thin films on organic layers at lower temperatures and lower energies to provide thin films of appropriate refractive indexes, while not damaging the organic layer and providing a barrier to environmental agents to provide a longer lifetime for the organic layer (e.g., the electronic device).

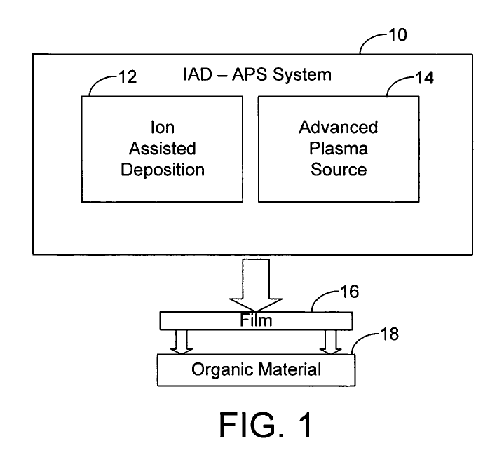

The thin film structure is grown using an Ion Assisted Deposition (IAD) 12 with an Advanced Plasma Source (APS) system 14 as shown in FIG. 1. The IAD-APS system 10 uses an advanced plasma source that can form high quality thin film 16 (e.g., nitride/oxide/oxynitride dielectrics) on the layer of organic material 18 at low temperatures (e.g., about 30 to 100° C.). Using the low temperature deposition processes of the LAD-APS system 10 avoids damaging the underlying organic substrate or layers 18. In addition, the IAD-APS system 10 can provide thin films 16 having better adhesion and coating material quality at low temperatures relative to other systems.

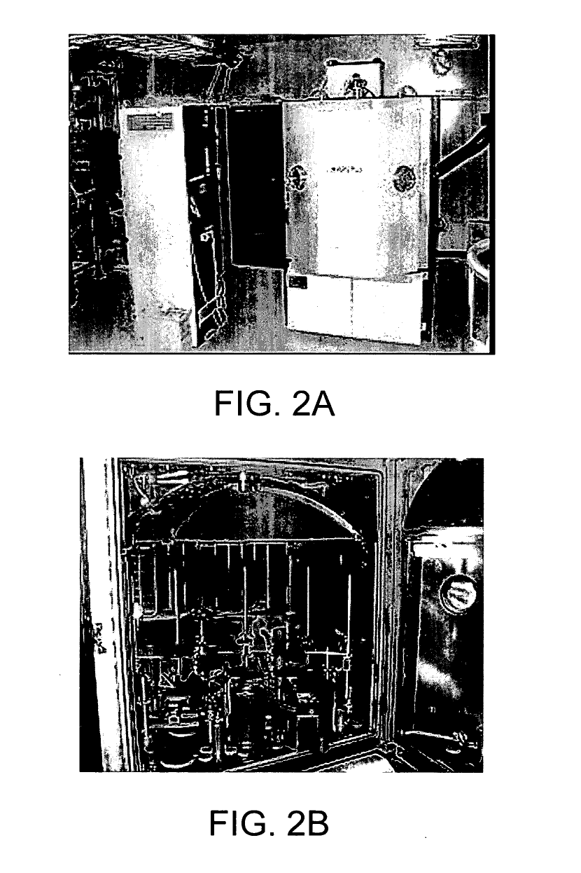

Embodiments of the IAD-APS system, such as the one described in reference to FIG. 1, are powerful deposition tools that provide several benefits not possible by other vacuum deposition techniques. The IAD-APS system and processes associated therewith are cost effective encapsulation and passivation processes. The IAD-APS system includes, but is not limited to, a multi-pocket e-beam evaporator and four thermal evaporators as shown in FIGS. 2A and 2B and described in more detail in the Examples.

For a particular embodiment, a dome shaped substrate holder is heated and rotates continuously during deposition for better film uniformity and coverage. A plasma source includes a large area LaB₆ cathode, a cylindrical anode tube and a solenoid magnet. The source is located in the center of the process chamber bottom. The LaB₆ cylindrical cathode is indirectly heated by a graphite filament heater. A DC voltage between the anode and the cathode creates a glow discharge with a hot electron emitter, supplied with a noble gas such as argon, for example. Mobility of the plasma electrons is strongly increased in the axial direction and strongly decreased in the radial direction because of the magnetic field of the solenoid. Electrons spiral along the magnetic field lines and therefore the plasma is extracted into the direction of the substrate holder. Reaction gases are introduced through a ring shower located on top of the anode tube. Reactive gases get activated and partly ionized due to the high plasma density directly above the plasma source. The ionization of the reactive gas lowers the reactive gas pressure, which is used to grow stoichiometric films. Since the plasma spreads the total volume between the plasma source and the substrate holder, the evaporant also becomes partly ionized for deposition. During the IAD process, the surface mobility of the surface growth species is increased due to momentum transfer from the accelerated plasma ions to the condensing film molecules, which in turn produces denser and high quality films at lower deposition temperatures. Additionally, the LaB₆ cathode is compatible with oxygen. Therefore, the system is well suited for oxide processes as well as nitrogen processes. The system is designed for a total ion current of more than about 1 to 5 A with excellent uniformity across the spherical substrate holder. Useful substrate area is over about 4000 to 9000 cm² and is well suited for mass production.

The structure including the thin film layer and the organic material (organic layer) can be included in devices, such as, but not limited to, electronic devices (e.g., organic material based devices). The electronic devices can include, but are not limited to, light emitting diodes (e.g., organic light emitting diodes), solid state lighting, flat panel displays (e.g., flat panel televisions, flat panel computer monitors, laptop displays, cell phone displays, personal assistant displays, and the like), solar cells, transistors, and other electrical components.

The organic layer can include organic layers used in the devices mentioned above. It should also be noted that the organic layer can include, but is not limited to, members of classes of materials known as hole transport layers, electron transport layers, phosphorescent materials, small molecule materials, polymer materials and the like. In particular, the composition of the organic layer may include, but is not limited to, materials such as Alq₃ (tris-(8-hydroxyquiniline) aluminum, commonly used as electron transport layers in LEDs, NPB (N,N′-diphenyl-N,N′-bis(1-naphthyl)-(1,1′-biphenyl)-4, 4′-diamine), commonly used as hole transport layer in LEDs, and polymer LEDs.

The thin film can be an oxynitride or oxide dielectric material. In particular, the thin film can be a metal oxynitride or a metal oxide dielectric material. The metal oxynitride or metal oxide dielectric material can be described as M1ₐO_{y}N_{z} and M1ₐM2_{b}O_{y}N_{z} or M1ₐOᵣ, and M1ₐM2_{b}Oᵣ, respectively. M includes the transition metals, the metalloids, the lanthanides, and the actinides. More specifically, M includes, but is not limited to, silicon (Si), aluminum (Al), titanium (Ti), zirconium (Zr), hafnium (Hf), tin (Sn), nickel (Ni), cobalt (Co), zinc (Zn), lead (Pb), molybdenum (Mo), vanadium (V), niobium (Nb), magnesium (Mg), tantalum (Ta), silver (Ag), iridium (Ir), platinum (Pt), palladium (Pd), gold (Au), gallium (Ga), gadolinium (Gd), lanthanum (La), yttrium (Y), and combinations thereof. In particular, M can be Si and Al. The values of a, b, y, z, q, and r can vary depending on M and the oxynitride or oxide dielectric material formed as well as the refractive index of the thin film. Due to the wide ranges of materials valences and stoichiometries available, the values of a, b, y, z, q, and r can be difficult to specify exactly. For example, silicon oxide can be made as SiO and SiO₂, and zirconium nitride can be produced as ZrN and Zr₃N₄. However, a, b, y, z, q, and r are each independently from about 0 to 4.

As mentioned above, the thin film can be a single layer or a plurality of layers. In an embodiment a multilayer thin film may include, but is not limited to, about 2 to 10 layers.

The thin films can have a thickness of about 10 to 1000 nm, about 20 to 1000 nm, about 20 to 500 nm, about 20 to 250 nm, about 20 to 150 nm, and about 20 to 100 nm. It should be noted that additional thickness ranges could be obtained in increments of 10 nm. The length and width of the thin film layer depends, in part, on the organic layer and the device that the organic layer is to be used in.

The thin films can have a refractive index of about 1.4 to 2.3, about 1.6 to 2.2, about 1.6 to 2.1, about 1.6 to 2.0, about 1.6 to 1.9, and about 1.6 to 1.8.

It should be noted that the device that includes the thin film disposed on the organic layer has an enhanced lifetime according to tests to determine the ability of the thin film to limit the exposure of the organic layer to environmental degradation (e.g., oxygen and/or humidity). In general, the results for the testing suggest that the thin film would substantially or completely reduced the exposure of the organic layer to environmental degradation under accelerated aging conditions (e.g., about 50 C. and about 50% relative humidity). Specific details of the accelerated lifetime tests are discussed in the Example below.

The thin film can be formed using the IAD-APS system. In short, the process for producing the thin film includes forming a thin film of a material onto the layer of organic material at a temperature of about 25 to 150° C., about 30 to 90° C., and about 50 to 70° C. As an example, for SiON films, starting source materials can be SiO, Si or SiO₂. These materials are evaporated by electron beams in the case of Si and SiO₂ and by thermal evaporation in the case of SiO. The materials are deposited at a rate of about 0.1 to 2, 0.2 to 1.5, and 0.5 to 1 nm/s in a reactive environment supplied by the APS. The O and N content of the final product is controlled by the relative amounts of O and N in the plasma, the evaporation rates, and the energy of the ion assist. In general the ratio of O to N can range from about 0.0125 to 80, about 0.025 to 40, and about 0.1 to 10. Typical APS gas flow parameters used are about 0 to 80, about 2 to 40, and about 5 to 10 sccm of O₂ and about 0 to 80, about 2 to 40, and about 5 to 10 sccm of N₂ with an additional flow of Ar from about 4 to 16, about 6 to 12, and about 8 to 12 sccm, while the ion energies utilized are from about 40 to 300 eV, about 40 to 250 eV, about 40 to 200 eV, about 40 to 160 eV, about 70 to 150 eV, and about 90 to 160 eV.

In an embodiment, the structure has a silicon oxynitride (SiON) thin film layer (or a plurality of layers) deposited on (passivating) a layer of an organic material. The thin film acts as an encapsulating material. The thin film is a barrier to environmental agents, and has an index of refraction of about 1.4 to 2.3. The IAD-APS system can form a denser thin film layer than other techniques despite the lower temperature of the deposition and without damaging the layer of organic material. As mentioned above, the thin film layer can include multiple thin film layers.

Preliminary accelerated aging data at 50° C. and 50% R.H. indicate that the IAD SiON thin film passivated organic films showed only minor emission spectra changes in both intensity and shape for at least two months, whereas the uncoated organic films degraded completely within two days under the same accelerated aging conditions as described herein.

### EXAMPLES

Now having described the embodiments of the present disclosure, in general, the following Examples describe some additional embodiments of the present disclosure. While embodiments of present disclosure are described in connection with the following examples and the corresponding text and figures, there is no intent to limit embodiments of the present disclosure to this description. On the contrary, the intent is to cover all alternatives, modifications, and equivalents included within the spirit and scope of embodiments of the present disclosure.

### Example 1

The LAD process makes use of a unique advanced plasma source that can form high quality nitride/oxide dielectrics on organic surfaces at low temperature. This is critical in avoiding damage to OLED layers. Ion assisted deposition (IAD) with an Advanced Plasma Source (APS) system is a unique process for thin film coating supported by plasma ions that can provide much better adhesion and coating material quality with great layer thickness accuracy in terms of both uniformity and growth rate. FIGS. 2A and 2B show digital images of an embodiment of the APS system. The system includes a multi-pocket e-beam evaporator and four thermal evaporators. The dome shaped substrate holder is heated and rotates continuously during deposition for better film uniformity and coverage.

LAD, with the APS as shown in FIGS. 2A and 2B, is a powerful deposition tool that provides several benefits not possible by other vacuum deposition techniques. The plasma source includes a large area LaB₆ cathode, a cylindrical anode tube, and a solenoid magnet. The source is located in the center of the process chamber bottom. The LaB₆ cylindrical cathode is indirectly heated by a graphite filament heater. A DC voltage between anode and cathode creates a glow discharge with a hot electron emitter, supplied with a noble gas such as argon. Mobility of the plasma electrons is strongly increased in the axial direction and strongly decreased in the radial direction because of the magnetic field of the solenoid. Electrons spiral along the magnetic field lines, and therefore the plasma is extracted into the direction of the substrate holder. Reaction gases are introduced through a ring shower located on top of the anode tube. Reactive gases get activated and partly ionized due to the high plasma density directly above the plasma source. The ionization of the reactive gas lowers the reactive gas pressure, which allows growth of stoichiometric films. Since the plasma spreads the total volume between the plasma source and the substrate holder, the evaporant also becomes partly ionized for deposition. During the IAD process, the surface mobility of the surface growth species is increased due to momentum transfer from the accelerated plasma ions to the condensing film molecules, which in turn produces denser and high quality films at lower deposition temperatures. The LaB₆ cathode is compatible with oxygen. Therefore, the system is well suited for oxide processes. The system is designed for a total ion current of more than 5 A with excellent uniformity across the spherical substrate holder. Useful substrate area is over 9000 cm² and is well suited for mass production.

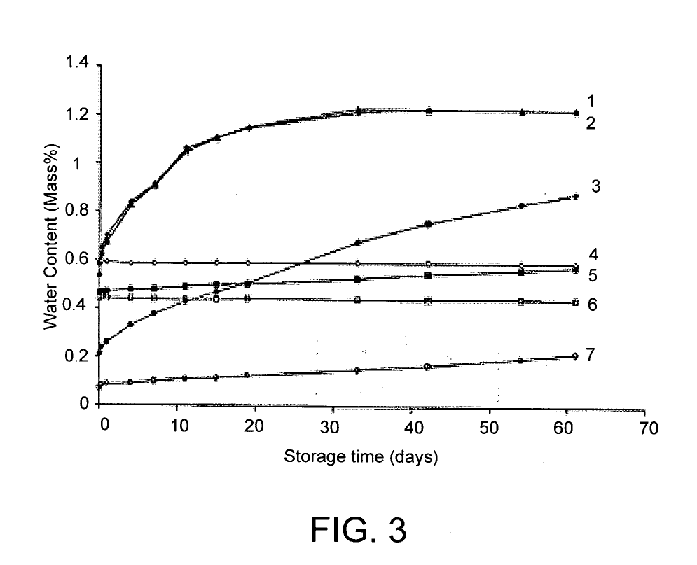

IAD deposited SiO₂ films also exhibited a more impervious structure as compared to plasma enhanced CVD (PECVD) deposited SiO₂. Very thin films of SiO₂ deposited by IAD utilized in optical chemical/biological detectors provided stable detector operation almost immediately as compared to PECVD coatings which took many hours to stabilize due to environmental moisture permeation of the films. Also, shown in FIG. 3 is a qualitative comparison of water permeability of different coatings on the same CR39 polymer lenses as reported by Schulz.

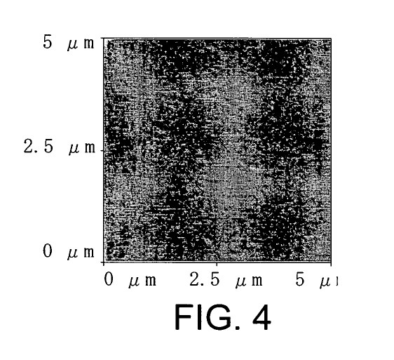

Curve 1 is the result of uncoated CR39. Curve 2 is the result of a CR39 lens dip coated with scratch-resistant layer. Curve 3 is the water content of a lens with a non IAD physical vapor deposition (PVD) deposited antireflection multilayer. Curve 4 is the result of a lens coated with a scratch-resistant layer and an antireflection multilayer, and curve 5 is a lens coated with an antireflection multilayer, and the lens of curve 6 was coated with a scratch-resistant layer. All coatings of curves 4, 5, and 6 were deposited by IAD. Curve 7 is the multilayer result from a lens with a dip-coated scratch-resistant layer and a PVD deposited antireflection layer. As indicated in FIG. 3, the water content in both IAD coated lenses (curves 4 and 6) were essentially constant throughout the experiment, indicating a very efficient moisture blockage effect by IAD processed coatings. Direct comparison of IAD and PVD process can be drawn from curve 3 and curve 5 since they are both coated with the same antireflection coatings. The lens with coating 3 had lower water content at the beginning due to higher deposition temperature. The multilayer coating acted as a better water barrier as indicated by curve 3 and curve 7. Multilayer deposition is extremely simple for the LAD system of the present disclosure since the system was designed with the capability of high accuracy multilayer deposition. FIG. 4 is an AFM scan of a SiON thin film deposited on a silicon substrate by the IAD process. As indicated in FIG. 4, the film had a smooth morphology with minimal defects. It was found by microscopic studies that IAD films had a much smoother surface compared to higher temperature deposition processes due to larger grain sizes obtained when deposited at high temperatures. This result fits well with the OLED requirement of low temperature deposition. A smoother surface can also help reduce the pinhole density in the encapsulation layer of the device.

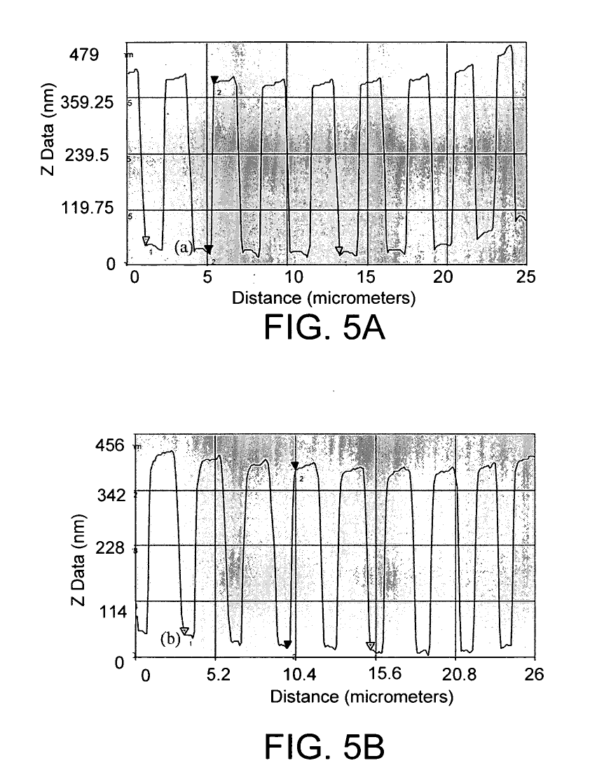

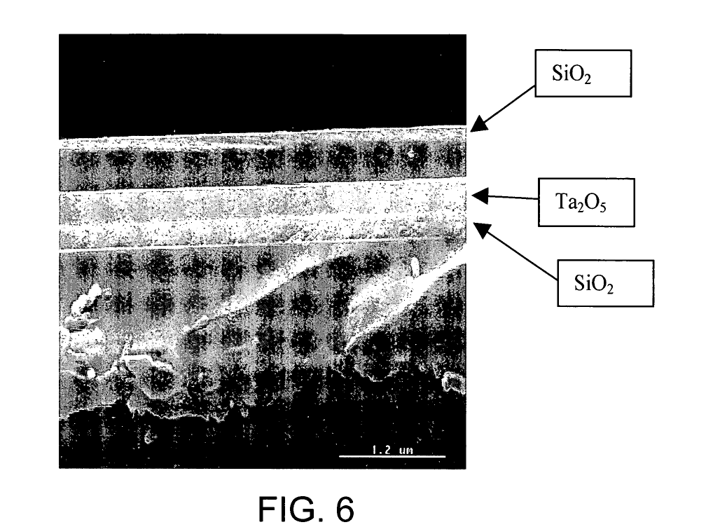

FIGS. 5A and 5B show an AFM profile analysis of uncoated and IAD coated gratings etched in a fuse silica substrate. FIG. 5A is the uncoated grating profile, and FIG. 5B is the same grating coated with an LAD ZnS film. As indicated in FIGS. 5A and 5B, the ZnS film can be uniformly coated at the bottom of the grating with a 400 nm grating depth. This shows the applicability of the IAD process to coating morphological structures as may be encountered in organic electronic devices. Shown in FIG. 6 is the SEM cross section of a multilayer IAD film showing the dense amorphous microstructure of the IAD films

Studies showed that ion bombardment damage to the organic layer can be minimized with proper deposition conditions. The ion energy of an advanced IAD system is very low compared to a conventional sputtering system. The typical ion energy of the system of the present disclosure is less than 160 eV, whereas the ion energy of a RF sputtering system is in the order of two thousand electron volts. The typical ion energy is about 500eV for magnetron sputtering. The ion energy of the IAD-APS system can also be adjusted easily by changing the system bias and ion current for minimized film damage.

### Example 2

It is believed that a moisture leak rate <10⁻⁵ g/m²/day is needed for an OLED lifetime better than 1 year. Therefore, a Ca thin film is used to test thin film efficiency. A 200 nm Ca thin film was thermally evaporated in an IAD system with a deposition rate of 0.4 nm/s as a test layer. A 150 nm SiON thin film is deposited on top of the Ca film with the following conditions:

1. Substrate temperature: about 50° C.

2. Nitrogen flow rate: about 20 sccm

3. Ar flow rate: about 16 sccm

4. Deposition rate: about 0.2 nm/s

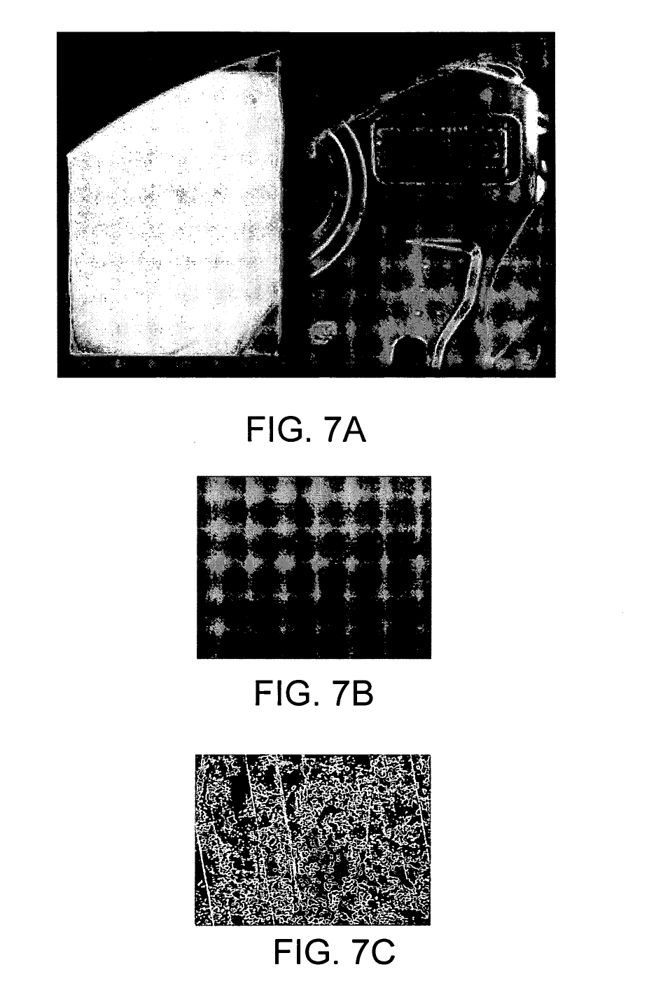

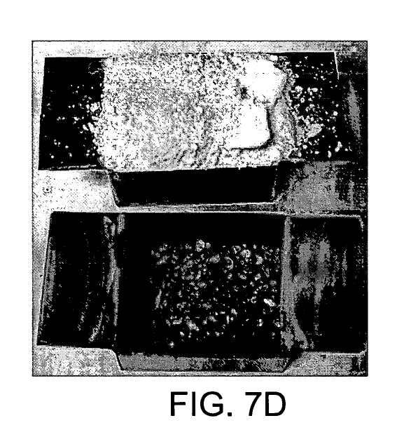

FIGS. 7A through 7D illustrate digital images of an H₂O permeation test using Ca. FIG. 7A illustrates a Ca metal film that is coated with SiON film after about 7 months. FIG. 7B illustrates a Nomarski picture of the Ca metal film shown in FIG. 7A. FIG. 7C illustrates a Nomarski picture of a melting Ca surface with no barrier layer protection.

Ca metal film samples that are passivated with SiON lasted at least about 2 weeks under 50° C. with a 50% relative humidity accelerated aging condition. Using careful substrate cleaning procedures, and one-step processes, the samples showed no sign of degradation for at least about 7 months as shown in FIG. 7A. However, the Ca film with no thin film layer melted away within 2 minutes of exposure to atmosphere.

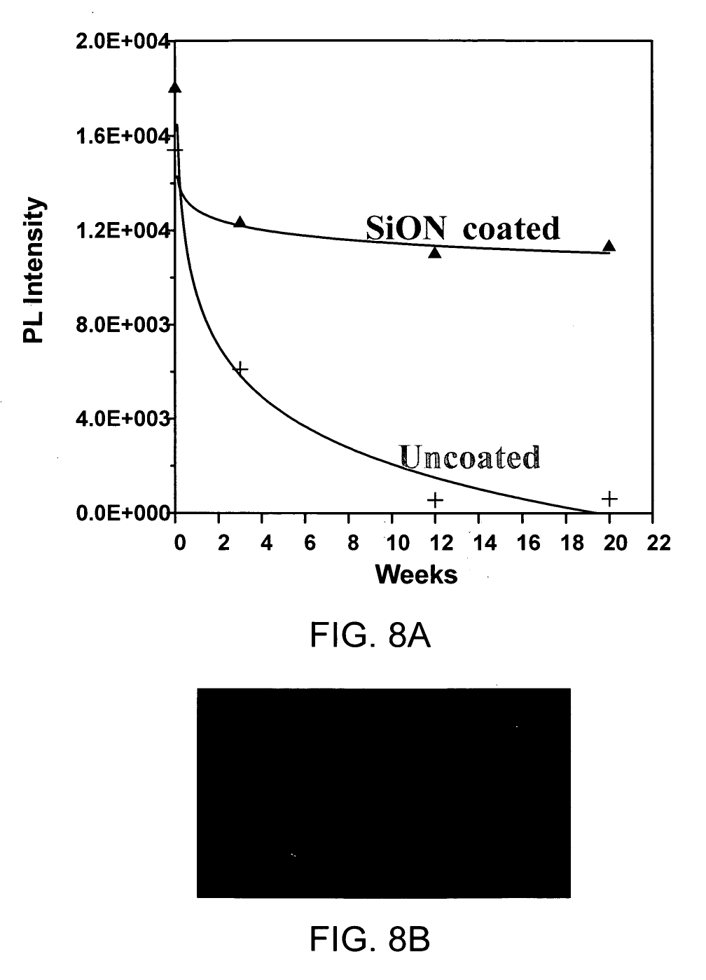

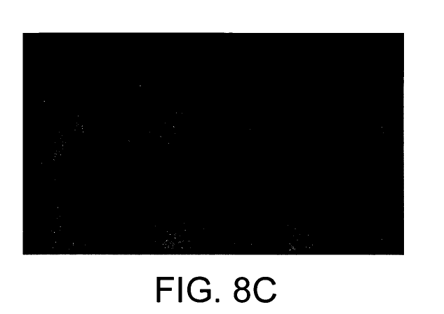

FIG. 8A shows the PL lifetime test of a Poly(n-Vinyl Carbazole) thin film under 50° C. with a 50% relative humidity accelerated aging condition. As indicated in the figure, the PL intensity of the organic film coated with the IAD moisture barrier stabilized at very early stage (<1 week). However, the PL intensity of the uncoated film continued to decrease until the sample was totally nonluminescent. FIG. 8B illustrates a digital image of the samples at above zero weeks, and FIG. 8C illustrates a digital image of the samples at above 3 weeks aging.

It should be emphasized that the above-described embodiments of the present disclosure, particularly, any “preferred” embodiments, are merely possible examples of implementations, merely set forth for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

1. A method of forming a thin film layer, comprising:
providing a layer of an organic material; and
forming a thin film of a material onto the layer of organic material at a temperature of about 25 to 150° C. and at an energy of about 40 to 300 eV, wherein the layer of organic material is not damaged, and wherein the thin film has a refractive index of about 1.4 to 2.3.

2. The method of claim 1, wherein the thin film is formed onto the layer of organic material at a temperature of about 30 to 70° C.

3. The method of claim 1, wherein the thin film is formed onto the layer of organic material at an energy of about 90 to 160 eV.

4. The method of claim 1, wherein the thin film has a refractive index of about 1.6 to 1.8.

5. The method of claim 1, wherein the thin film is an oxynitride.

6. The method of claim 5, wherein the oxynitride is silicon oxynitride.

7. The method of claim 1, wherein the thin film is selected from an aluminum oxide, an aluminum oxynitride, and combinations thereof.

8. The method of claim 1, wherein the thin film layer and the layer of organic material are part of an electronic device.

9. The method of claim 1, wherein the thin film layer and the layer of organic material are part of a device selected from: an organic light emitting diode, a solar cell, and a transistor.

10. The method of claim 1, wherein the thin film is a multilayer thin film.

11. A structure, comprising:
a thin film layer deposited on a layer of an organic material, wherein the thin film has a refractive index of about 1.4 to 2.3, and wherein the thin film is an environmental barrier that protects the layer of organic material from environmental agents.

12. The structure of claim 11, wherein the thin film is an oxynitride.

13. The structure of claim 12, wherein the oxynitride is silicon oxynitride.

14. The structure of claim 11, wherein the thin film is selected from an aluminum oxide, an aluminum oxynitride, and combinations thereof.

15. The structure of claim 11, wherein the thin film layer and the layer of organic material are part of an electronic device.

16. The structure of claim 11, wherein the thin film layer and the layer of organic material are part of a device selected from: an organic light emitting diode, a solar cell, and a transistor.

17. The structure of claim 11, wherein the thin film has a refractive index of about 1.6 to 1.8.

18. The structure of claim 11, wherein the environmental agents are selected from: oxygen, moisture, and combinations thereof.

19. The structure of claim 11, wherein a luminescence of the layer of organic material is unchanged after months of accelerated aging.

20. The structure of claim 11, wherein the thin film is a multilayer thin film.
